(19) United States
(12) Patent Application Publication
(10) Pub. No.: US 2015/0228514 A1
(43) Pub. Date: Aug. 13, 2015

(54) Multi Fluid Cooling System for Large Temperature Range Chuck

(71) Applicant: Axcelis Technologies, Inc., Beverly, MA (US)

(72) Inventors: William Davis Lee, Newburyport, MA (US); Steve Drummond, Merrimac, MA (US)

(73) Assignee: Axcelis Technologies, Inc., Beverly, MA (US)

(21) Appl. No.: 14/178,681

(22) Filed: Feb. 12, 2014

(51) Int. Cl. H01L 21/67; H01L 21/683

(52) U.S. Cl. CPC H01L 21/67109; H01L 21/6833

(57) ABSTRACT

An electrostatic clamping system has an electrostatic chuck having one or more electrodes and a clamping surface and one or more fluid passages therethrough. A plurality of fluid sources has a respective plurality of fluids associated therewith, wherein each of the plurality of fluids are chemically distinct from one another and has a respective viable fluid temperature range associated therewith. A thermal unit is configured to heat and/or cool the plurality of fluids to one or more predetermined temperature setpoints. A valve assembly is configured to selectively fluidly couple each of the plurality of fluid sources to the one or more fluid passages of the electrostatic chuck. A controller is also configured to selectively fluidly couple the one or more fluid passages of the electrostatic chuck with a selected one or more of the plurality of fluid sources via a control of the valve assembly.

### TECHNICAL FIELD

The present disclosure relates generally to workpiece carriers and more specifically to a electrostatic chuck configured to flow a plurality of coolants therethrough over a large range of temperatures.

### BACKGROUND

Workpiece supports are often utilized in the semiconductor industry for supporting and clamping workpieces or substrates during plasma-based or vacuum-based semiconductor processes such as ion implantation, etching, chemical vapor deposition (CVD), etc. Electrostatic clamps (ESCs), for example, implement electrostatic clamping forces between the workpiece and the ESC to electrostatically attract the workpiece to a clamping surface of the ESC during processing. It is often desirable to cool or heat the workpiece during processing, wherein a fluid is flowed through a fluid path within the ESC in order to provide the cooling or heating of the workpiece while the workpiece resides on the ESC.

### SUMMARY

The present disclosure details a workpiece support for supporting and uniformly cooling or heating a workpiece disposed thereon at a wide range of temperatures in a semiconductor processing system. Accordingly, the following presents a simplified summary of the disclosure in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

In accordance with one exemplary aspect an electrostatic clamping system is disclosed, wherein an electrostatic chuck having one or more electrodes and a clamping surface is provided. The electrostatic chuck is configured to support and electrostatically clamp a workpiece thereto via an electrical current passed through the one or more electrodes. The electrostatic chuck, for example, comprises one or more fluid passages therethrough.

A plurality of fluid sources, for example, have a respective plurality of fluids associated therewith. In one example, each of the plurality of fluids are chemically distinct from one another and has a respective viable fluid temperature range associated therewith. A thermal unit is further configured to heat and/or cool the plurality of fluids to one or more predetermined temperature setpoints.

According to another exemplary aspect, a valve assembly is further provided, wherein the valve assembly comprising one or more automated valves configured to selectively fluidly couple each of the plurality of fluid sources to the one or more fluid passages of the electrostatic chuck.

Further, a controller is configured to selectively open and close the one or more automated valves based on one or more flushing conditions. Thus, the one or more fluid passages of the electrostatic chuck are selectively fluidly coupled with a selected one or more of the plurality of fluid sources. The one or more flushing conditions, for example, are based on one or more of a flushing algorithm and a lookup table relating the viable fluid temperature range and chemical compatibility associated with each of the plurality of fluids to one or more predetermined process temperatures associated with a processing of the workpiece on the electrostatic chuck.

The above summary is merely intended to give a brief overview of some features of some embodiments of the present invention, and other embodiments may comprise additional and/or different features than the ones mentioned above. In particular, this summary is not to be construed to be limiting the scope of the present application. Thus, to the accomplishment of the foregoing and related ends, the invention comprises the features hereinafter described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a block diagram of an exemplary electrostatic clamping system in accordance with several aspects of the present disclosure.

FIG. 2 is a block diagram of a processing system comprising an exemplary electrostatic clamping system, in accordance with various other aspects of the present disclosure.

### DETAILED DESCRIPTION

In some semiconductor processes, such as ion implantation processes, it can be desirable to provide a thermal path (e.g., a cooling path or a heating path) between a workpiece (e.g., a semiconductor wafer) and a support that holds the workpiece during processing in order to maintain a predetermined temperature at the workpiece. The present disclosure provides an electrostatic chuck having a fluid disposed therein, wherein a flow of the fluid within the workpiece support is maintained at a substantially constant mass flow rate as the fluid travels with respect to a surface of the workpiece.

The present disclosure is thus directed generally toward a system, apparatus, and method for supporting workpieces and transferring thermal energy between a workpiece and an electrostatic chuck in a semiconductor processing system. Accordingly, the present invention will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling. Furthermore, it is to be appreciated that functional blocks or units shown in the drawings may be implemented as separate features or circuits in one embodiment, and may also or alternatively be fully or partially implemented in a common feature or circuit in another embodiment. For example, several functional blocks may be implemented as software running on a common processor, such as a signal processor. It is further to be understood that any connection which is described as being wire-based in the following specification may also be implemented as a wireless communication, unless noted to the contrary.

In semiconductor processing, an electrostatic chuck or clamp (ESC) is not only implemented to support and maintain a position of a workpiece, but can be further utilized to heat or cool the workpiece before, during, or after processing. However, some processes are performed at significantly high or low temperatures (e.g., −100° C. to +500° C.). Such a large temperature range of operation, however, can prove difficult in conventional systems that utilize a single fluid, as the single fluid must function as a heat transfer fluid over the entire range of temperatures. For example water freezes solid at or below 0° C., but it performs well as a cooling fluid while liquid, or in two phase (liquid-vapor) flow. If a need arises to cool below 0° C., however, a different fluid that has a lower freezing point would have to be used as a heat transfer fluid. Likewise, very high temperatures benefit from a high-temperature compatible fluid that boils at significantly high temperatures. Thus, the present disclosure provides a system and apparatus configured to heat and/or cool a workpiece over a large temperature range using a plurality of fluids in a manner not seen heretofore.

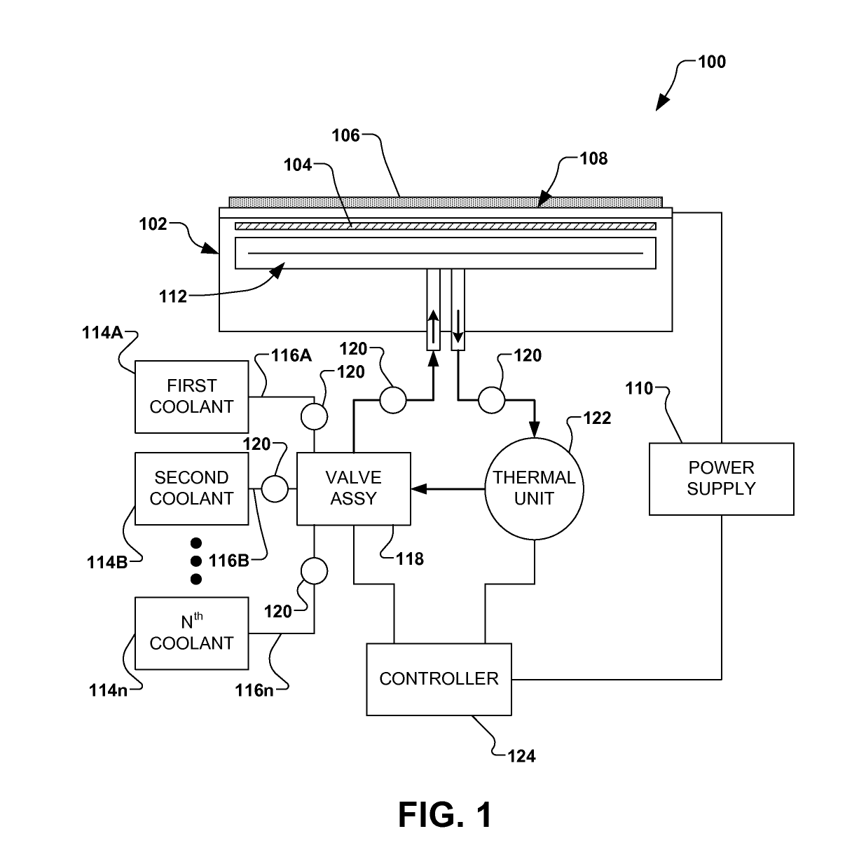

Referring now to the Figures, FIG. 1 illustrates an exemplary electrostatic clamping system 100 in accordance with several aspects of the present disclosure. According to one example, the electrostatic clamping system comprises an electrostatic chuck (ESC) 102 comprising one or more electrodes 104 configured to electrostatically attract a workpiece 106 to a surface 108 thereof via an electrical current passed through the one or more electrodes by a power supply 110. As stated above, in various semiconductor processes, it is desirable to heat and/or cool the ESC 102 via a fluid that is flowed through the ESC in order for the fluid to function as a heat transfer medium to heat and/or cool the workpiece 106 prior to, concurrent with, or after processing, such as an ion implantation. For example, the electrostatic clamping system 100 of the present disclosure in easily capable of performing over a very large temperature range it (e.g., −100° C. to +500° C.).

The ESC 102 of the present disclosure comprises one or more fluid passages 112 (also called channels or paths) therethrough. A plurality of fluid sources 114A-114n having a respective plurality of fluids 116A-116n associated therewith are further provided, wherein each of the plurality of fluids are chemically distinct from one another, and each has a respective viable fluid temperature range associated therewith that is optimized for different temperature ranges.

For example, the plurality of fluids 116 comprise one or more of water, fluorocarbons, air, compressed dry air (CDA), dry nitrogen, Argon, and various other liquids and gases that each have differing boiling point and/or freezing points from the remaining of the plurality of fluids and/or are suitable for flushing the one or more fluid passages 112, thus preventing freezing or other deleterious effects of operating at different temperatures. In other words, the viable fluid temperature range associated with each fluid 116 comprises one or more of a liquid temperature range and gaseous temperature range at which said each of the plurality of fluids remains in one or more of a liquid and gaseous state under either atmospheric pressure or other elevated or lowered pressures.

According to one example, a valve assembly 118 is provided and configured to selectively fluidly couple each of the plurality of fluid sources 114 to the one or more fluid passages 112 of the ESC 102. The valve assembly 118, for example, comprises one or more automated valves 120 associated with the plurality of fluid sources 114 and one or more fluid passages 112. A thermal unit 122 is further provided in fluid communication with the one or more fluid passages 112 and is configured to heat and/or cool the plurality of fluids 116 to one or more predetermined temperature setpoints. While one thermal unit 122 is illustrated in FIG. 1, it should be understood that a plurality of thermal units are also contemplated, wherein each thermal unit is associated with a respective fluid source 114.

Further, a controller 124 is provided configured to selectively fluidly couple the one or more fluid passages 112 of the ESC 102 with a selected one or more of the plurality of fluid sources 114 via a control of the valve assembly 118. For example, the controller 124 is configured to open and close the one or more automated valves 120, therein selectively fluidly coupling the one or more fluid passages 112 of the ESC 102 to the selected one or more of the plurality of fluid sources 114.

In accordance with one exemplary aspect, the controller 124 is configured to open and close the one or more automated valves 120 based on one or more flushing conditions. The one or more flushing conditions, for example, comprise a chemical compatibility between the plurality of fluids. Alternatively, in another example, the one or more flushing conditions comprise one or more of a boiling and freezing point of one or more of the plurality of fluids 116

In another example, the one or more flushing conditions are based on one or more of a flushing algorithm and a lookup table relating the viable fluid temperature range associated with each of the plurality of fluids 116 to one or more predetermined process temperatures associated with a processing of the workpiece 106 on the ESC 102. For example, the controller 124 is configured to flush a first of the plurality of fluids 116A from the one or more fluid passages 112 of the ESC 102 with a second of the plurality of fluids 116B when at least one of the one or more flushing conditions is met. The controller 124 can be further configured to flush one or more of the first and second of the plurality of fluids 116A, 116B from the one or more fluid passages 112 of the electrostatic chuck 102 with a third of the plurality of fluids 116C based when at least another one of the one or more flushing conditions is met. It is thus contemplated that any number of fluids 116 and fluid sources 114 can be provided and are considered as falling within the scope of the present disclosure.

In accordance with one example, the flushing algorithm discussed above comprises a timing sequence associated with a length of time during which the one or more automated valves 120 are opened and/or closed. Further, the flushing algorithm can comprise various other criteria or instructions, such as criteria related to chemical compatibility of the plurality of fluids 116 to one another, etc. The lookup table, for example, can further relate the one or more predetermined temperature setpoints associated with the thermal unit 122 to the viable fluid temperature range associated with each of the plurality of fluids 116 and the one or more predetermined process temperatures.

The controller 124, in another example, is further configured to control the thermal unit 122. For example, the controller 124 is configured to control the thermal unit 122 based, at least in part, on the selected one or more of the plurality of fluid sources 114. In another example, the controller is configured to control the heating and/or cooling the one or more of the plurality of fluids 116 associated with the selected one or more of the plurality of fluid sources 114 to the one or more predetermined temperature setpoints.

In accordance with yet another example, the one or more fluid passages 112 comprise a plurality of discrete fluid passages (not shown), wherein the valve assembly 118 is configured to selectively fluidly couple one or more of the plurality of fluid sources 114 to one or more of the plurality of discrete fluid passages of the ESC 102. For example, the ESC 102 can comprise two or more different cooling paths for each of the plurality of fluids 116. Thus, the valve assembly 118 is configured to allow switching or swapping of fluids 116 based on desired processing conditions. As such, a gas (e.g. air, CDA, dry nitrogen, Argon, etc.) can be utilized as one of the plurality of fluids 116 for purging the ESC 102, thus clearing one fluid out of the ESC prior to a new fluid being introduced.

In a system that uses different channels for the plurality of fluids 116, a similar purge scheme can be included. Such a purging scheme can be important for a fluid 116 such as water, as water has a tendency to expand when it freezes. In other scenarios, however, purging may not be necessary. For example, if a fluid 116 that contracts upon freezing were used, such a fluid might not harm the system 100 by simply leaving the fluid in place (e.g., not stopping the fluid from flowing, but not purging it from the system 100), thus not allowing it to freeze. Such a scenario might also be advantageous from a heat transfer stand point, in that now the space (e.g., the one or more fluid passages 112) that would otherwise be void would have material in it, thus aiding in the transfer of heat.

Further, since it is possible that thermal properties of the fluids 116 can change with temperature, swapping fluids can be desirable to optimize heat transfer in a given temperature range. Likewise, it can be desirable to swap fluids 116 based on the process parameters, such as high-power ion implantations that may require a high flow of fluid (e.g., water), whereas low-power ion implantations can be cooled sufficiently by flowing a gas (e.g., nitrogen).

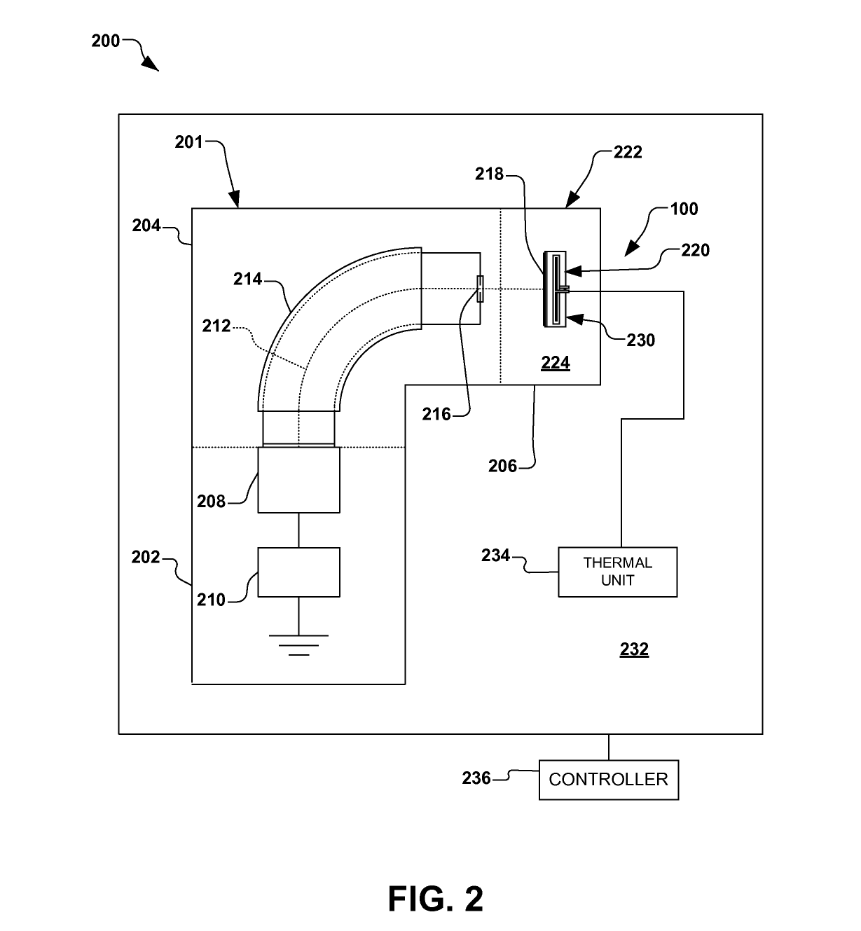

In accordance with another aspect of the present disclosure, FIG. 2 illustrates an exemplary processing system 200, wherein the electrostatic clamping system 100 of FIG. 1 can be advantageously implemented. The processing system 200 of FIG. 2 in the present example comprises an ion implantation system 201, however various other types of processing systems are also contemplated, such as plasma processing systems, reactive ion etching (RIE) systems, or other semiconductor processing systems. The ion implantation system 201, for example, comprises a terminal 202, a beamline assembly 204, and an end station 206.

Generally speaking, an ion source 208 in the terminal 202 is coupled to a power supply 210 to ionize a dopant gas into a plurality of ions and to form an ion beam 212. The ion beam 212 in the present example is directed through a beam-steering apparatus 214, and out an aperture 216 towards the end station 206. In the end station 206, the ion beam 212 bombards a workpiece 218 (e.g., a semiconductor such as a silicon wafer, a display panel, etc.), which is selectively clamped or mounted to a chuck 220 (e.g., an electrostatic chuck or ESC, such as the ESC 102 of FIG. 1). Once embedded into the lattice of the workpiece 218 of FIG. 2, the implanted ions change the physical and/or chemical properties of the workpiece. Because of this, ion implantation is used in semiconductor device fabrication and in metal finishing, as well as various applications in materials science research.

The ion beam 212 of the present disclosure can take any form, such as a pencil or spot beam, a ribbon beam, a scanned beam, or any other form in which ions are directed toward end station 206, and all such forms are contemplated as falling within the scope of the disclosure.

According to one exemplary aspect, the end station 206 comprises a process chamber 222, such as a vacuum chamber, wherein a process environment 224 is associated with the process chamber. The process environment 224 generally exists within the process chamber 222, and in one example, comprises a vacuum produced by a vacuum source (e.g., a vacuum pump) coupled to the process chamber and configured to substantially evacuate the process chamber.

During an implantation utilizing the ion implantation system 201, energy can build up on the workpiece 218 in the form of heat, as the charged ions collide with the workpiece. Absent countermeasures, such heat can potentially warp or crack the workpiece 218, which may render the workpiece worthless (or significantly less valuable) in some implementations. The heat can further cause the dose of ions delivered to the workpiece 218 to differ from the dosage desired, which can alter functionality from what is desired. For example, if a dose of 1×10¹⁷ atoms/cm² are desired to be implanted in an extremely thin region just below the outer surface of the workpiece 218, undesirable heating could cause the delivered ions to diffuse out from this extremely thin region such that the dosage actually achieved is less than 1×10¹⁷ atoms/cm². In effect, the undesirable heating can “smear” the implanted charge over a larger region than desired, thereby reducing the effective dosage to less than what is desired. Other undesirable effects could also occur from the undesirable heating of the workpiece 218. It may be further desirable to implant ions at a temperature below or above an ambient temperature, such as to allow for desirable amorphization of the surface of the workpiece 218 enabling ultra shallow junction formation in advanced CMOS integrated circuit device manufacturing. In such cases, cooling of the workpiece 218 is desirable. In other circumstances, it is desirable to further heat the workpiece 218 during implantation or other processing in order to aid in processing (e.g., such as a high-temperature implantation into silicon carbide).

Thus, in accordance with another example, the chuck 220 comprises a controlled temperature chuck 230, wherein the controlled temperature chuck is configured to both support the workpiece and to selectively cool, heat, or otherwise maintain a predetermined temperature on the workpiece 218 within the process chamber 222 during the exposure of the workpiece to the ion beam 212. As such, it should be noted that the controlled temperature chuck 230 in the present example can comprise a sub-ambient temperature chuck configured to support and cool the workpiece 218, or a super-ambient temperature chuck configured to support and heat the workpiece within the process chamber 222. In another example, the controlled-temperature chuck 230 can provide no heating or cooling to the workpiece.

The controlled temperature chuck 230, for example, comprises the electrostatic chuck 102 configured to cool or heat the workpiece 218 to a processing temperature that is considerably lower or higher than an ambient or atmospheric temperature of the surroundings or external environment 232 (e.g., also called an “atmospheric environment”), respectively. A thermal system 234 may be further provided, wherein, in another example, the thermal system is configured to cool or heat the controlled temperature chuck 230, and thus, the workpiece 218 residing thereon, to the processing temperature. For example, the controlled temperature chuck 230 and thermal system 234 of FIG. 2 can comprise some or all of the components of the electrostatic clamping system 100 of FIG. 1. In one example, the electrostatic clamping system 100 is further controlled via a controller 236 associated with a control various aspects of the processing system 200.

Although the invention has been shown and described with respect to a certain embodiment or embodiments, it should be noted that the above-described embodiments serve only as examples for implementations of some embodiments of the present invention, and the application of the present invention is not restricted to these embodiments. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application. Accordingly, the present invention is not to be limited to the above-described embodiments, but is intended to be limited only by the appended claims and equivalents thereof.

1. An electrostatic clamping system, comprising:
an electrostatic chuck having one or more electrodes and a clamping surface, wherein the electrostatic chuck is configured to support and electrostatically clamp a workpiece thereto via an electrical current passed through the one or more electrodes, and wherein the electrostatic chuck comprises one or more fluid passages therethrough;
a plurality of fluid sources having a respective plurality of fluids associated therewith, wherein each of the plurality of fluids are chemically distinct from one another and has a respective viable fluid temperature range associated therewith;
a thermal unit configured to heat and/or cool the plurality of fluids to one or more predetermined temperature setpoints;
a valve assembly configured to selectively fluidly couple each of the plurality of fluid sources to the one or more fluid passages of the electrostatic chuck; and
a controller configured to selectively fluidly couple the one or more fluid passages of the electrostatic chuck with a selected one or more of the plurality of fluid sources via a control of the valve assembly.

2. The electrostatic clamping system of claim 1, wherein the valve assembly comprises one or more automated valves, wherein the controller is configured to open and close the one or more automated valves, therein selectively fluidly coupling the one or more fluid passages of the electrostatic chuck to the selected one or more of the plurality of fluid sources.

3. The electrostatic clamping system of claim 2, wherein the controller is configured to open and close the one or more automated valves based on one or more flushing conditions.

4. The electrostatic clamping system of claim 3, wherein the one or more flushing conditions are based on one or more of a flushing algorithm and a lookup table relating the viable fluid temperature range associated with each of the plurality of fluids to one or more predetermined process temperatures associated with a processing of the workpiece on the electrostatic chuck.

5. The electrostatic clamping system of claim 4, wherein the controller is configured to flush a first of the plurality of fluids from the one or more fluid passages of the electrostatic chuck with a second of the plurality of fluids when at least one of the one or more flushing conditions is met.

6. The electrostatic clamping system of claim 5, wherein the controller is further configured to flush one or more of the first and second of the plurality of fluids from the one or more fluid passages of the electrostatic chuck with a third of the plurality of fluids based when at least another one of the one or more flushing conditions is met.

7. The electrostatic clamping system of claim 4, wherein the flushing algorithm comprises a timing sequence associated with a length of time during which the one or more automated valves are opened and/or closed.

8. The electrostatic clamping system of claim 4, wherein the lookup table further relates the one or more predetermined temperature setpoints to the viable fluid temperature range associated with each of the plurality of fluids and the one or more predetermined process temperatures.

9. The electrostatic clamping system of claim 3, wherein the one or more flushing conditions comprise a chemical compatibility between the plurality of fluids.

10. The electrostatic clamping system of claim 1, wherein the controller is further configured to control the thermal unit, therein heating and/or cooling the one or more of the plurality of fluids associated with the selected one or more of the plurality of fluid sources to the one or more predetermined temperature setpoints.

11. The electrostatic clamping system of claim 1, wherein the controller is further configured to control the thermal unit based, at least in part, on the selected one or more of the plurality of fluid sources.

12. The electrostatic clamping system of claim 1, wherein a boiling point of one of the plurality of fluids differs from a boiling point of the remaining of the plurality of fluids.

13. The electrostatic clamping system of claim 1, wherein a freezing point of one of the plurality of fluids differs from a freezing point of the remaining of the plurality of fluids.

14. The electrostatic clamping system of claim 1, wherein the one or more fluid passages comprise a plurality of discrete fluid passages, and wherein the valve assembly is configured to selectively fluidly couple one or more of the plurality of fluid sources to one or more of the plurality of discrete fluid passages of the electrostatic chuck.

15. The electrostatic clamping system of claim 1, wherein the viable fluid temperature range of each of the plurality of fluids comprises a temperature range at which said each of the plurality of fluids remains in one or more of a liquid state and gaseous state.

16. An electrostatic clamping system, comprising:
an electrostatic chuck having one or more electrodes and a clamping surface, wherein the electrostatic chuck is configured to support and electrostatically clamp a workpiece thereto via an electrical current passed through the one or more electrodes, and wherein the electrostatic chuck comprises one or more fluid passages therethrough;
a plurality of fluid sources having a respective plurality of fluids associated therewith, wherein each of the plurality of fluids are chemically distinct from one another and has a respective viable fluid temperature range associated therewith;
a thermal unit configured to heat and/or cool the plurality of fluids to one or more predetermined temperature setpoints;
a valve assembly comprising one or more automated valves configured to selectively fluidly couple each of the plurality of fluid sources to the one or more fluid passages of the electrostatic chuck; and
a controller configured to selectively open and close the one or more automated valves based on one or more flushing conditions, therein selectively fluidly coupling fluidly coupling the one or more fluid passages of the electrostatic chuck with a selected one or more of the plurality of fluid sources.

17. The electrostatic clamping system of claim 16, wherein the one or more flushing conditions are based on one or more of a flushing algorithm and a lookup table relating the viable fluid temperature range associated with each of the plurality of fluids to one or more predetermined process temperatures associated with a processing of the workpiece on the electrostatic chuck.

18. The electrostatic clamping system of claim 16, wherein the one or more flushing conditions comprise a chemical compatibility between the plurality of fluids.

19. The electrostatic clamping system of claim 16, wherein the viable fluid temperature range of each of the plurality of fluids comprises a liquid temperature range at which said each of the plurality of fluids remains in a liquid state.

20. An electrostatic clamping system, comprising:
an electrostatic chuck having one or more electrodes and a clamping surface, wherein the electrostatic chuck is configured to support and electrostatically clamp a workpiece thereto via an electrical current passed through the one or more electrodes, and wherein the electrostatic chuck comprises one or more fluid passages therethrough;
a plurality of fluid sources having a respective plurality of fluids associated therewith, wherein each of the plurality of fluids are chemically distinct from one another and has a respective viable fluid temperature range associated therewith;
a thermal unit configured to heat and/or cool the plurality of fluids to one or more predetermined temperature setpoints;
a valve assembly comprising one or more automated valves configured to selectively fluidly couple each of the plurality of fluid sources to the one or more fluid passages of the electrostatic chuck; and
a controller configured to selectively open and close the one or more automated valves based on one or more flushing conditions, therein selectively fluidly coupling fluidly coupling the one or more fluid passages of the electrostatic chuck with a selected one or more of the plurality of fluid sources, wherein the one or more flushing conditions are based on one or more of a flushing algorithm and a lookup table relating the viable fluid temperature range and chemical compatibility associated with each of the plurality of fluids to one or more predetermined process temperatures associated with a processing of the workpiece on the electrostatic chuck.
